(19) United States
(12) Patent Application Publication
(10) Pub. No.: US 2026/0160809 A1
(43) Pub. Date: Jun. 11, 2026

(54) Probe card with calibrated probe head capacitive distance monitor

(71) Applicant: FormFactor, Inc., Livermore, CA (US)

(72) Inventors: Kevin Ayers, Hillsboro, OR (US); Ryan Garrison, Hood River, OR (US); Dennis Rosenauer, Tigard, OR (US); Benjamin Lyle Crabtree, San Diego, CA (US); Christopher Paul Lemoine, Mountain View, CA (US); Corey J Anderson, Hillsboro, OR (US)

(21) Appl. No.: 19/410,684

(22) Filed: Dec. 5, 2025

Related U.S. Application Data
(60) Provisional application No. 63/729,805, filed on Dec. 9, 2024.

(51) Int. Cl. G01R 31/28; G01B 7/02; G01R 1/073; G01R 1/44

(52) U.S. Cl. CPC G01R 31/2891; G01R 1/07357; G01R 1/44; G01B 7/023

(57) ABSTRACT

In probe heads making a large number of contacts to a device under test using flexible probes, the actual overtravel can differ from the programmed overtravel because of the total contact force from all the probes. Thus it is often important to measure the actual overtravel instead of relying on the programmed overtravel and the actual overtravel being the same. Here we provide improved sensing of actual overtravel using capacitive distance sensors that are calibrated to account for the effect of the device under test on capacitive distance measurements.

### CROSS REFERENCE TO RELATED APPLICATIONS

This application claims priority from U.S. Provisional Patent Application 63/729,805 filed Dec. 9, 2024, which is incorporated herein by reference.

### GOVERNMENT SPONSORSHIP

None.

### FIELD OF THE INVENTION

This invention relates to electrical probing of a device under test.

### BACKGROUND

When arrays of electrical probes are used to make temporary electrical contact to a device under test, programmed overtravel (POT) is one of the important design parameters. This is the programmed overtravel of the prober chuck.

However, the actual overtravel (AOT) can differ from the POT because of mechanical motion of the device under test when it is probed. Here the AOT is the vertical distance that the flexible probes actually compress by when the probe head makes contact to the device under test.

Because of this possibility, it is of interest to measure AOT, especially for large arrays of probes that can exert significant total force on the device under test when probing. Two known methods for doing this are the clay puck method and the push pin method.

In the clay puck method, clay pucks are disposed around the probe array and the amount they are compressed by is measured optically, e.g., with a probe head camera. In the push pin method, one or more push pins are disposed in the stiffener to serve as measurements of AOT. Here also the probe head camera can be used to make the measurement.

Both these known approaches have the disadvantage of being non-resetting mechanical displacement methods. These methods do not provide continuous monitoring and require manual re-setting for subsequent uses.

### SUMMARY

In this work, one or more capacitive sensors are disposed in the probe head to measure probe head spring displacement. These sensors are calibrated to account for the effect of the device under test on capacitive distance measurements

In operation, embodiments provide continuous monitoring of probe head spring deflection. Monitoring of spring head deflection enables measurement of AOT/POT, which is a critical ratio needed to properly set up a high pin count probe card.

An exemplary construction includes:
i) a capacitive distance sensor, mounted on or near a probe head spring; where
ii) the capacitive distance sensor has a DUT-specific calibration.

The use of a continuously monitoring displacement sensor is more accurate and once set up, enables AOT/POT measurement in a fraction of the time compared to current AOT/POT measurement methods.

The main advantage of this solution is that continuous displacement monitoring is provided, enabling quick set up of measurements and the ability to record transient displacement events, which is not possible with traditional methods. Accuracy of the measurement is also significantly improved. Conventional methods, as described below, have the disadvantages of: being slow, requiring manual resetting, making contact with the DUT, having no ability to measure transients, and having lower accuracy.

### BRIEF DESCRIPTION OF THE DRAWINGS

FIG. 1 is a side view of a conventional probe head.

FIG. 2 schematically shows overtravel.

FIG. 3 shows two known methods of measuring actual overtravel.

FIG. 4 shows a side view of an exemplary embodiment of the invention.

FIG. 5 is a top view of the example of FIG. 4.

FIG. 6 schematically shows one approach for DUT-specific calibration.

FIGS. 7-8 schematically show two approaches for in-situ DUT-specific calibration.

### DETAILED DESCRIPTION

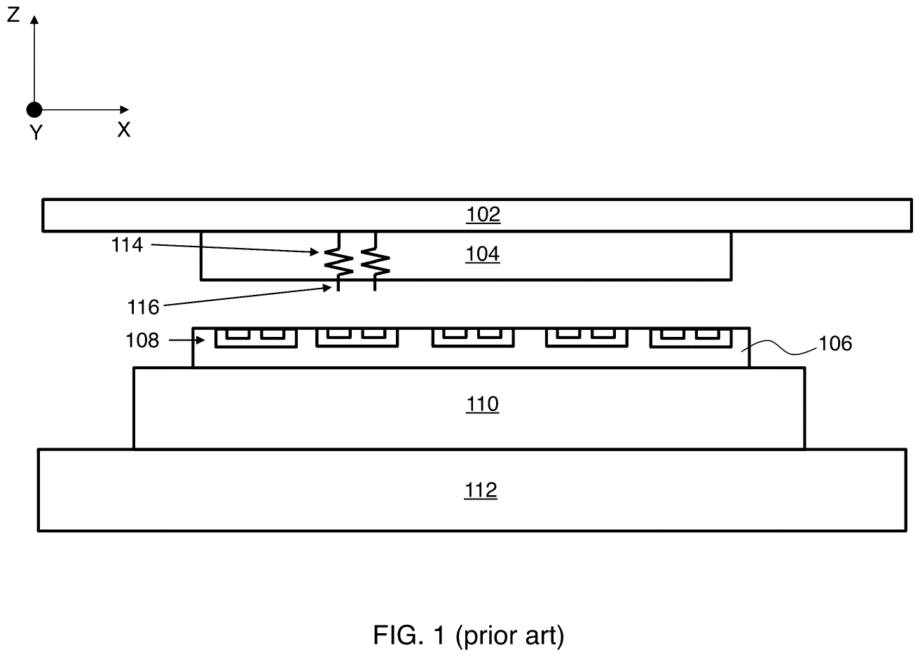

FIG. 1 is a side view of a conventional probe head. Here 102 schematically shows the probe card assembly, which can include a printed circuit board (PCB), stiffener etc.

Feature 104 is the probe head, 106 is the device under test (DUT) substrate, 108 are the DUTs, 110 is a chuck for supporting the DUTs, 112 is a chuck translation stage that typically provides X/Y/Z motion and rotation about the Z axis with all motions calibrated by the probe system, 114 are compliant features of probe head 104 and 116 are the probe contacts (also referred to as probe tips).

Substrate 106 could be a monolithic wafer or individual devices chips arrayed on a substrate such as adhesive film within a film carrier.

Compliance 114 is provided by the flexibility of the probes. As is well known in the art, probes for making temporary electrical contact to the device under test are often flexible, and this work relates to flexible probes.

The prober has methods to measure both the surface of the DUTs and the tips of the probes, and precisely control the relative X/Y/Z positions and rotation around Z. Some probers may also contain adjustments for the planarity of the DUTs and substrate (e.g., rotation around X and/or Y axes).

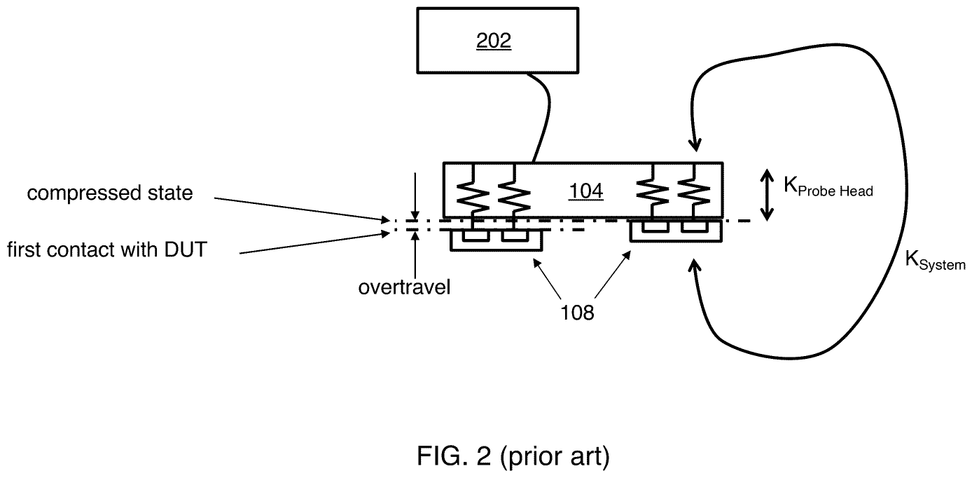

FIG. 2 schematically shows overtravel. Here 202 is the test equipment connected to probe head 104. Overtravel is the difference in DUT-to-probe head distance between first contact (FIG. 2, left) and final compressed state (FIG. 2, right).

Programmed overtravel (POT) is the overtravel programmed into the prober chuck translation stage. Actual overtravel (AOT) is the actual overtravel achieved after accounting for the finite compliance of the overall system. AOT is always less than POT due to the finite compliance of the system (chuck, translation stage, overall prober mechanical structure, probe card assembly support structure, and probe card assembly itself). The spring constant (compliance) of the probe head itself (K_{Probe Head}) IS typically well understood and characterized, but the spring constant (compliance) of the remaining system (K_{system}) is typically unknown and can vary across the test setups. First contact is often measured by gradually increasing the Z-height of the chuck while looking for electrical first contact as observed by the associated electrical test instrumentation that is connected to the probes. The instrumentation has a standard test that detects continuity between any two DUT electrodes and observing such continuity test results while gradually increasing z-height can detect first contact.

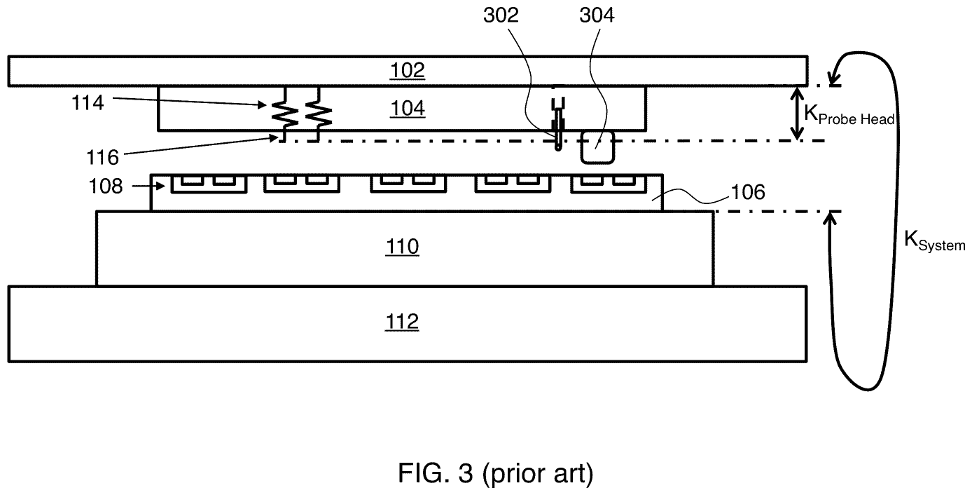

FIG. 3 shows two known methods of measuring actual overtravel. Traditional methods for measuring AOT include push pin and clay puck. In the push-pin approach a pin 302 is extended below the plane of the probe tips. The chuck is incrementally raised until electrical first contact. The chuck is then raised further until the desired programmed overtravel is achieved. Then the probe card is removed and the push pin is measured versus the plane of the probe tips. This is the actual overtravel. The clay puck approach is similar to the push pin approach, except deformation of a clay puck 304 is used to measure the actual overtravel.

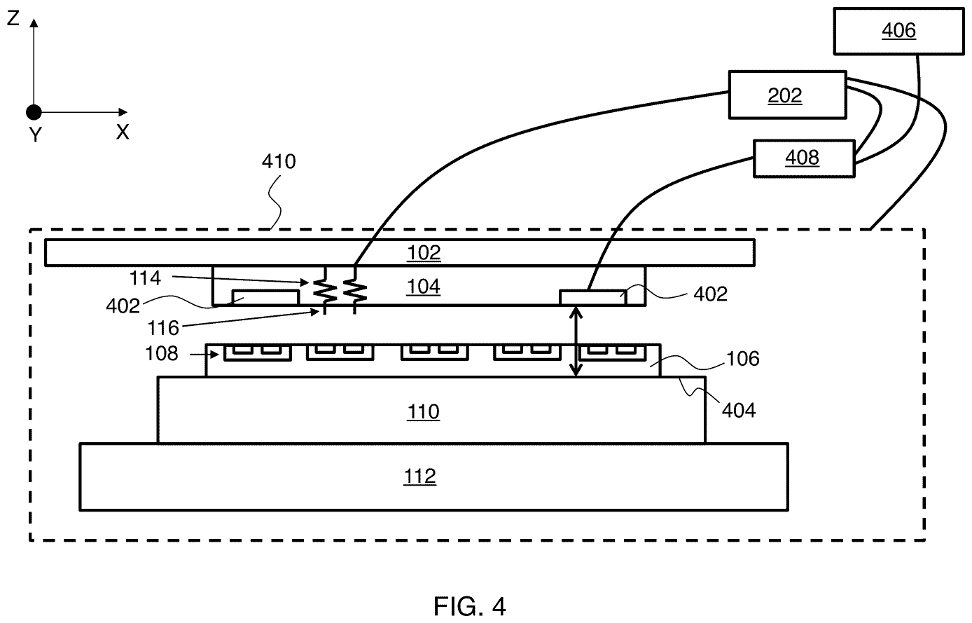

FIG. 4 shows an exemplary embodiment of the invention. Here 406 is a computer or interface and 408 is a controller for one or more capacitive sensors 402 configured to measure a distance (double headed arrow) between probe head 104 and a top surface 404 of chuck 110. The overall system is referenced as prober 410.

Test equipment 202 is typically the ‘master’ of the test cell and can control the X/Y/Z movement of prober 410. Alternatively, the user can manually control prober 410 via a control panel.

Controller 408 can be integrated or remote, and in the integrated case the controller might be mechanically attached to the probe card assembly as a daughter card or module, or fabricated into the probe card PCB. Controller 408 can include signal processing circuitry for capacitive sensors 402.

One or more capacitive sensors 402 can be employed to provide various functions. A single sensor can measure distance only. Two sensors can measure tilt in one direction. Three or four sensors can measure tilt in two directions (planarity versus the chuck). Five or more sensors would enable measurement of bowing (convex or concave) across the surface of the probe head.

These capacitive sensors are calibrated as described in further detail below. Typically, each sensor has its own calibration (i.e., independent calibration).

To use this solution for AOT measurement, use the electrical first contact method described above to measure first contact, and use the calibration factors from the independent calibration to measure subsequent overtravel as the probe springs are compressed.

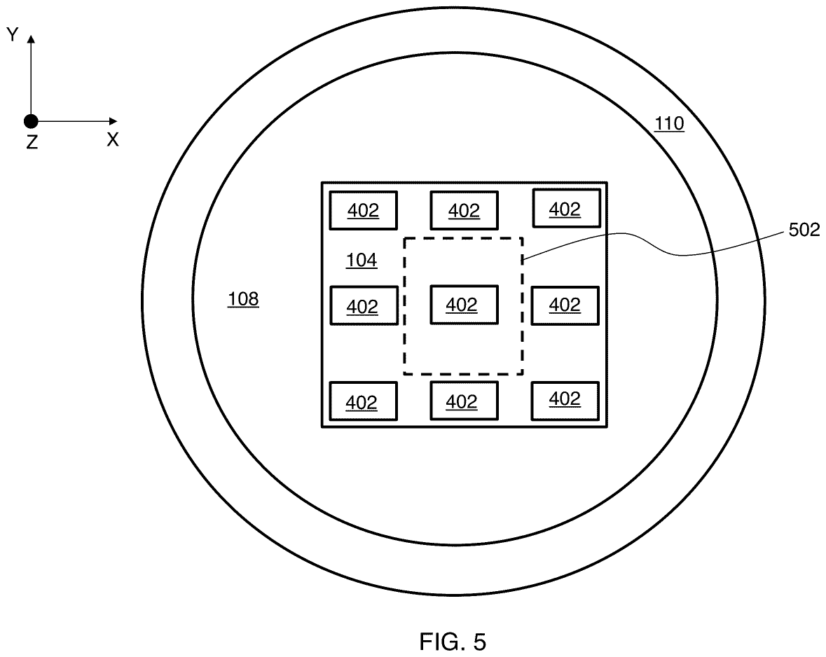

FIG. 5 is a top view of the example of FIG. 4, showing the sensors 402 and probe array 502 over the DUT substrate 108 and chuck 110. In some cases there may be no room to put multiple capacitive sensor in the active probe area 502, due to size constraints (e.g., not enough room in between the probe contacts). Typically there will be sufficient room around the periphery of the active probe contact area 502, as shown.

As indicated on FIG. 4, the capacitive sensors 402 measure distance to top surface 404 of chuck 110 through the DUT substrate 106. The calibration considered herein accounts for this distance measurement through the DUT because a naive bare calibration of signal vs. distance through air is insufficiently accurate.

Thus we consider DUT-specific calibration. A DUT-specific calibration of the capacitive distance sensor is a measured relation between distance and sensor signal for a specific type of DUT. Such a calibration can be used in all cases where the sensor that was calibrated is used to measure distance to the chuck through that kind of DUT. If the DUT changes (i.e., it has a different thickness or the like), the calibration may need to be redone for this new kind of DUT. Similarly, a new calibration may be needed if the sensor is changed. The calibration can be performed in a test jig or the like where a negligible difference between AOT and POT can be ensured (e.g., by ensuring there are no contact forces from probes). DUT-specific calibration can be performed using a copy of the DUT that will be tested in operation, or with a dummy target configured to match thickness and substrate composition of the DUT.

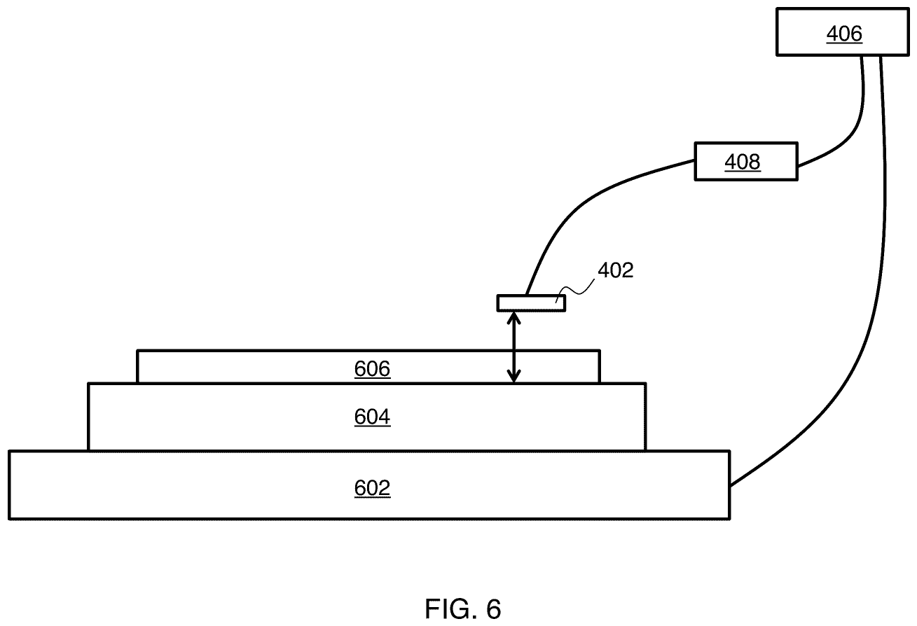

FIG. 6 schematically shows one approach for DUT-specific calibration. Here 602 is a z-translation stage, 604 is a target that simulates chuck 110 in relevant part (i.e., is electrically conductive) and 606 is a dummy substrate that simulates DUT substrate 106 and DUTs 108 in relevant part. For example dummy substrate 606 can be the DUT (or an identical part), or it can be a dummy wafer having the same composition and thickness of DUT substrate (a silicon wafer having 0.1 mm thickness would be a typical example).

More specifically, calibration of individual sensors can be done using a setup that:
1) supports the sensor 402 in a fixed location.
2) has a movable suitable target surface 604 with a known calibrated distance from the sensor 402.
3) has a calibration routine contained in the controller 408 or computer 406 that moves the target 604 to different distances from the sensor and measures the resulting capacitance.
4) uses a cubic spline or other interpolation method to derive an equation that translates raw capacitance measurements to calibrated distance measurements.
5) These measurements assume that air and dummy substrate 606 are the dielectrics between the sensor and target. Using this method, we can derive a series of calibration factors with different simulated DUT substrates. In most applications the substrate is silicon, and the thickness of the silicon will be the main determinant of the accuracy of the sensor. We can also assume a certain composition of the target material, as well as other environmental factors such as temperature.
6) The controller can have memory such that one or more sensors with known calibration factors can be attached to the controller and provide calibrated distance measurements, assuming the same environment and target factors.

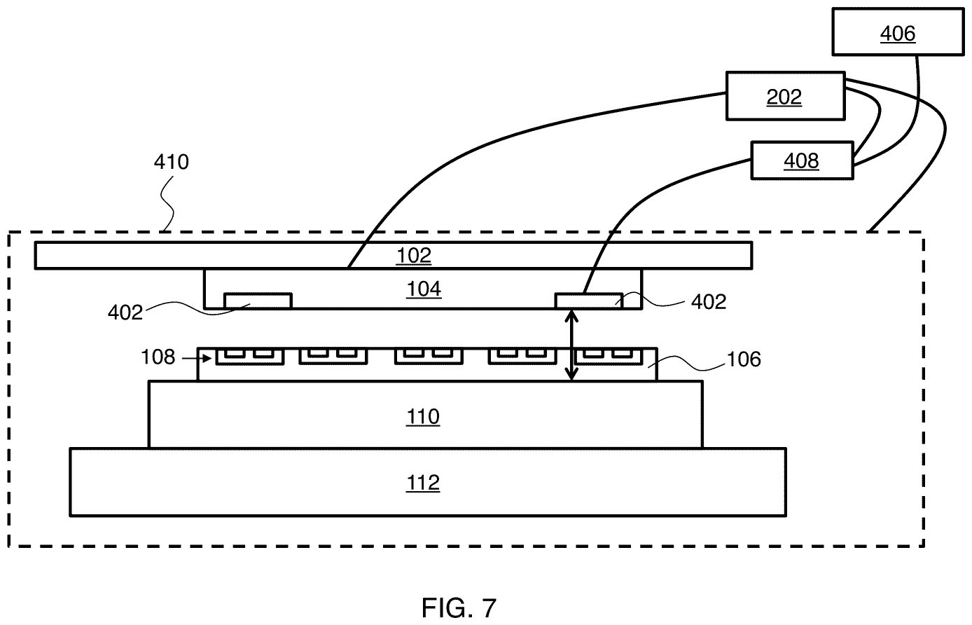

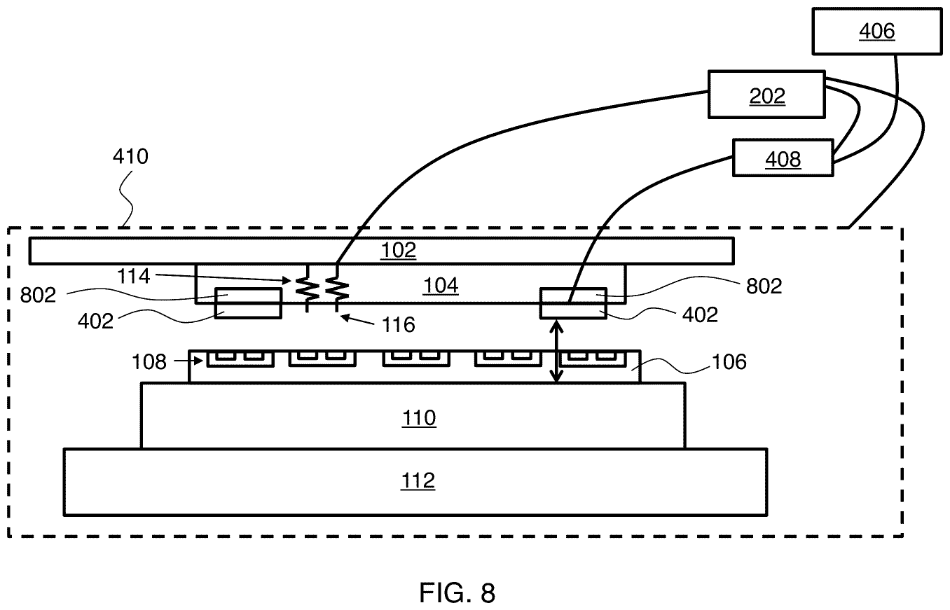

FIGS. 7-8 schematically show two approaches for in-situ DUT-specific calibration. To further improve accuracy, the sensors can be calibrated in situ within the prober setup and with the target DUT. This will offer the most accurate measurements. In this case, the sensors need to move through their full range of motion versus the chuck, and without the probes making contact with the DUTs. There are two ways to achieve this. 1) install a probe head that does not have the probe contacts installed (FIG. 7), or 2) use a shim to temporarily move the sensors closer to the chuck (FIG. 8, here 802 are the shims). In this case, the prober chuck translation stage can be moved through a series of z-heights to acquire the raw capacitance readings at the known Z-heights, and without the effect of the probe contact compression that would cause deflection of the system. Then a method as described above can be used to derive the calibration factors for each sensor. If the probe head without probes is used, the calibration is copied over to a probe head including the probes and having the same sensors. If the shim is used, the shim thickness would be mathematically removed from the distance measurements.

1. Apparatus comprising:
a probe head;
a probe array of flexible probes disposed in the probe head and configured to make temporary electrical contact to a device under test (DUT);
a chuck having a top surface on which the DUT is disposed in operation;
at least one capacitive distance sensor disposed in the probe head and configured to measure a distance between the probe head and the top surface of the chuck through the DUT;
wherein the at least one capacitive distance sensor is calibrated to provide a DUT-specific calibration relating a sensor signal to a corresponding distance.

2. The apparatus of claim 1, further comprising signal processing circuitry for the at least one capacitive sensor.

3. The apparatus of claim 2, wherein the signal processing circuitry is disposed remotely from a probe card assembly that includes the probe head.

4. The apparatus of claim 2, wherein the signal processing circuitry is disposed in a probe card assembly that includes the probe head.

5. The apparatus of claim 1, further comprising at least one temperature sensor disposed in the probe head.

6. The apparatus of claim 5, wherein the DUT-specific calibration accounts for temperature.

7. The apparatus of claim 1, wherein the at least one capacitive distance sensor includes two or more capacitive distance sensors.

8. The apparatus of claim 7, wherein the two or more capacitive distance sensors are configured to provide a measurement of a tilt between the probe head and the top surface of the chuck.

9. The apparatus of claim 7, wherein the two or more capacitive distance sensors are configured to provide a measurement of planarity between the probe head and the top surface of the chuck.

10. The apparatus of claim 7, wherein the two or more capacitive distance sensors are configured to provide a measurement of convex or concave bowing between the probe head and the top surface of the chuck.

11. The apparatus of claim 7, wherein the two or more capacitive distance sensors are configured to provide synchronized sensor signals.

12. The apparatus of claim 1, wherein the DUT-specific calibration is performed using the DUT.

13. The apparatus of claim 1, wherein the DUT-specific calibration is performed using a dummy target configured to match thickness and substrate composition of the DUT.
